(19) United States
(12) Patent Application Publication
(10) Pub. No.: US 2004/0190321 A1
(43) Pub. Date: Sep. 30, 2004

(54) System of storing data of one of a variety of memory cards in a portable storage device

(75) Inventors: Ting-Wen Huang, Taipei Hsien (TW); Chia-Lung Hsu, Taipei Hsien (TW)

Correspondence Address: BACON & THOMAS, PLLC, 625 SLATERS LANE, FOURTH FLOOR, ALEXANDRIA, VA, 22314

(73) Assignee: Inventec Appliances Corp., Taipei Hsien (TW)

(21) Appl. No.: 10/394,259

(22) Filed: Mar. 24, 2003

(51) Int. Cl. G11C 5/06

(52) U.S. Cl. 365/63

(57) ABSTRACT

The present invention is to provide a system of storing data of one of a variety of memory cards in a portable storage device, wherein a storage media installed in the storage device can be implemented as an ordinary hard disk with a high memory capacity for storing data transferred from a memory card and uploading the data into an electronic device if needed, and be designed in a small size having a built-in power supply for easily being carried by a user while travelling.

### FIELD OF THE INVENTION

The present invention relates to data storages and more particularly to a system of storing data of one of a variety of memory cards (e.g., CF card, SD card, SM card, etc.) in a portable storage device.

### BACKGROUND OF THE INVENTION

Recently, the electronics technology has known a rapid, spectacular development leading to a continuous improvement of the computers and its peripherals. Also, various inexpensive software packages are available in a faster pace. As such, more people use the computers and peripherals in their daily life, work, and learning, resulting in a significant rise of sale of the computers and related products. For possessing a larger share of this booming and profitable market, all major computer and peripheral manufacturers endeavor to provide more advanced types of products constantly.

Recently developed digital cameras have the features of taking high resolution pictures and playing MPEG (Moving Picture Experts Group) image files. Hence, more people buy and use digital cameras. Unfortunately, a removable memory card of digital camera only has a small memory space and is high in cost. For example, a 128MB memory card used in a FUJI digital camera is capable of storing the mage files as follows:

| | | | |
|---|---|---|---|
| file specifications | 2832 | * 2128 | MPEG (30 frames/second) |
| file size | 18 MB | 460 K | 128 MB |
| number of pictures | 7 | 275 | 112 seconds |
| taken/second | | | |

As such, a user has to store the data of the memory card into a PC (personal computer) or a NB (notebook computer) while the memory card is full in memory. After that, the user can delete the data of the memory card for leaving space for future use of the digital camera in taking pictures which are again stored in the memory card.

In view of the above, the digital camera user has to carry either several memory cards or a NB while traveling. In a case while the memory space of a memory card being inserted in a digital camera is full after taking a sufficient number of pictures, the user can replace the memory card with a new one or upload the data of the memory card into the NB. Besides, A variety of memory cards such as CF card, SD card, SM card, etc. are commercially available and used in digital cameras, which may not be compatible with the memory card reader installed in the NB. Therefore, the digital camera user also has to carry another compatible card reader for transferring the data of the memory card to the NB while traveling, which is obviously very inconvenient for the user.

Thus, it is desirable among the manufactures to provide a portable storage device for storing data of one of a variety of memory cards (e.g., CF card, SD card, SM card, etc.) as a removable hard disk in small size and high memory capacity.

### SUMMARY OF THE INVENTION

A primary object of the present invention is to provide a system of storing data of one of a variety of memory cards in a portable storage device. By utilizing this, the above drawbacks of the prior art, such as the memory card of digital camera only has a small memory space and is high in cost, the digital camera user has to carry either several memory cards or a NB while traveling, and in case while the memory space of a memory card inserted in a digital camera is full after taking a sufficient number of pictures, the user can do nothing but replacing the memory card with a new one or upload data of the memory card into the NB, can then be overcome.

One object of the present invention is to provide a system of storing data of one of a variety of memory cards in a portable storage device, wherein a storage media installed in the storage device of the present invention can be implemented as an ordinary hard disk used in the PC or NB, which has a high memory capacity and is inexpensive. Furthermore, the storage device can be designed in small size and having a built-in power supply for easily being carried by the user while travelling. Moreover, the data in the storage device can be uploaded into an electronic device if needed. By utilizing the present invention, the above drawbacks of carrying several memory cards or a NB while traveling and replacing the memory card with a new one or upload data of the memory card into the NB while the memory card is full can be overcome.

The above and other objects, features and advantages of the present invention will become apparent from the following detailed description taken with the accompanying drawings.

### BRIEF DESCRIPTION OF THE DRAWINGS

FIG. 1 Is a block diagram of a system of storing data of one of a variety of memory cards in a portable storage device according to the invention; and

FIG. 2 is a flow chart showing a sequence of steps performed by the system of FIG. 1.

### DETAILED DESCRIPTION OF THE PREFERRED EMBODIMENTS

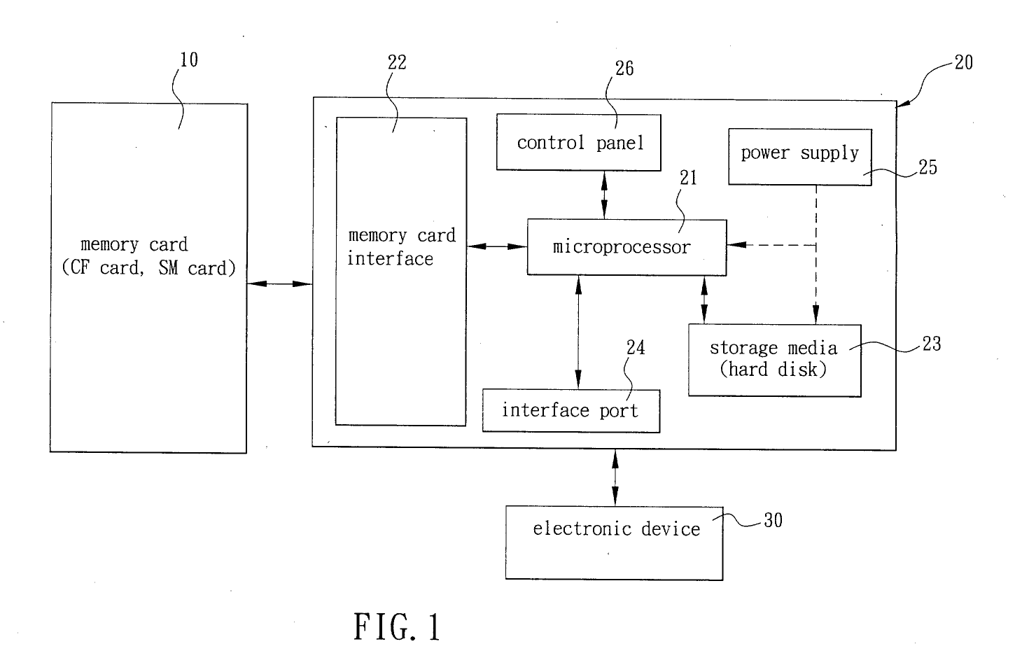

Referring to FIG. 1, there is shown a system of storing data of one of a variety of memory cards in a portable storage device in accordance with the invention. The system comprises a memory card 10 (e.g., CF card, SD card, SM card, or one of a variety of memory cards), which can be inserted in a digital camera (not shown). The data stored in the memory card 10 can then be transferred to a storage media 23 (e.g., hard disk) of a storage device 20 via a memory card interface 22 and a microprocessor 21 of the storage device 20 as commanded by the microprocessor 21. The data stored in the storage media 23 can also be transferred to an electronic device 30 (e.g., PC or NB) via the microprocessor 21 and an interface port 24 (e.g., Universal Serial Bus, abbreviated as USB) of the storage device 20 as commanded by the microprocessor 21. As such, a user can edit the data transferred to the electronic device 30 by taking advantage of a powerful editing feature thereof. Also, a power supply 25 is installed in the storage device 20 for supplying power to maintain a normal operation of all the components installed the storage device 20. Hence, the storage device 20 has a high memory capacity and can be easily carried in travelling.

Referring to FIG. 1 again, the storage device 20 comprises the microprocessor 21 for controlling the operation of all the components installed therein, processing the data and signals being transferred and stored in the system; the memory card interface 22 for interconnecting the memory card 10 and the microprocessor 21; the storage media 23 (e.g., hard disk) for storing data; the interface port 24 (e.g., USB port in the embodiment) for data communication between the storage device 20 and the electronic device 30; the power supply 25, which may be built into the storage device 20, for supplying power to maintain normal operation of all the components installed in the storage device 20; and a control panel 26 for inputting control instructions to the microprocessor 21, or outputting data received from the microprocessor 21.

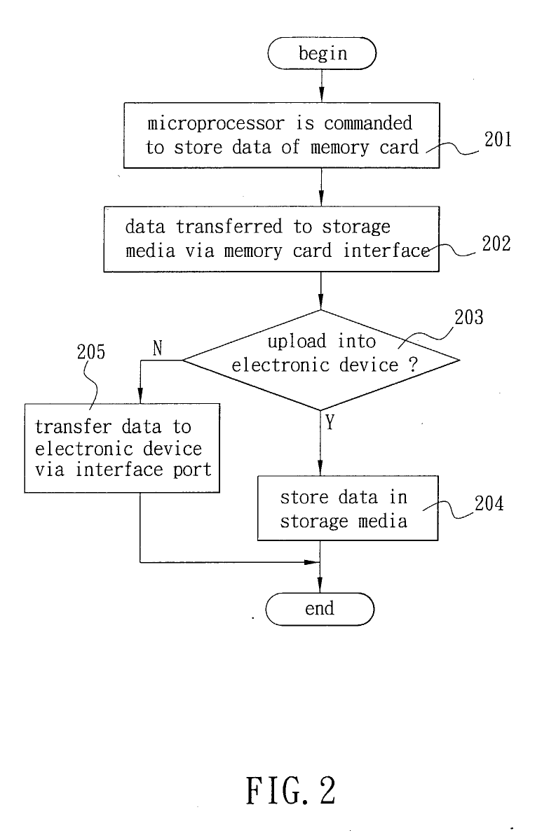

Referring to FIG. 2, there is shown a flow chart showing a sequence of steps performed by the system of FIG. 1 for storing the data of the memory card 10 connected to the memory card interface 22 of the storage device 20, which includes:

Step 201: First, while the microprocessor 21 of the storage device 20 receives a control instruction from the control panel 26 for storing data of the memory card 10 into the storage device 20;

Step 202: The microprocessor 21 transfers data of the memory card 10 to the storage media 23 (e.g., hard disk) via the memory card interface 22 and the microprocessor 21;

Step 203: The microprocessor 21 then determines whether the data of the memory card 10 should be uploaded into the electronic device 30 (e.g., PC or NB) if yes, the procedure goes to step 204; otherwise, the procedure goes to step 205;

Step 204: The microprocessor 21 directly transfer the data stored in the storage media 23 to the electronic device 30 for storage via the interface port 24 prior to ending the data transfer operation of the memory card 10;

Step 205: The microprocessor 21 stores the data in the storage media 23 directly prior to ending.

By utilizing this, the user can edit the data stored in the electronic device 30 by taking advantage of a powerful editing feature thereof.

In brief, the storage media 23 of the storage device 20 can be implemented as an ordinary hard disk used in the PC or NB, and can be designed in small size with high memory capacity having a built-in power supply 25 for easily being carried by the user during travelling. Moreover, the data in the storage device 20 can easily be uploaded into the electronic device 30 when needed. By utilizing the invention, the above drawbacks of carrying several memory cards while traveling for replacing the memory card in full, or carrying a NB along for uploading the data of the memory card into the NB, can be overcome.

While the invention has been described by means of specific embodiments, numerous modifications and variations could be made thereto by those skilled in the art without departing from the scope and spirit of the invention set forth in the claims.

1. A system for storing data from a plurality of memory cards in a portable storage device, comprising:
storage media installed in the portable storage device;
a memory card interface installed in the portable storage device for receiving data from a memory card;
a microprocessor installed in the portable storage device for transferring data stored in the memory card to the storage media via the memory card interface and the microprocessor, and
an interface port installed in the portable storage device for transferring the data stored in the storage media to an electronic device via the microprocessor.

2. The system of claim 1, wherein the microprocessor is operable to control all the components installed in the storage device and process the data and signals being transferred and stored therein, and the storage media is implemented as a hard disk operable to stored data.

3. The system of claim 2, wherein the portable storage device further comprises a built in power supply operable to supply power for maintaining normal operation of all the components of the portable storage device.

4. The system of claim 2, wherein the portable storage device further comprises a control panel for inputting control instructions to the microprocessor, or outputting data received from the microprocessor.

5. A method for storing data of one of a variety of memory cards in a portable storage device including storage media, a microprocessor, a memory card interface, and an interface port for connecting the portable storage device to an electronic device, wherein in response to storing data of one of a variety of memory cards connected to the memory card interface, the microprocessor of the portable storage device carries out the steps of:
receiving a control instruction from the control panel for transferring data from the memory card;
transferring the data from the memory card to the storage media via the memory card interface and the microprocessor;
determining whether the data should be uploaded into the electronic device by the microprocessor; and
transferring data stored in the storage media to the electronic device for storage via the interface port if the determination is positive.

6. The method of claim 5, further comprising the step of storing data in the storage media if the determination of whether the data should be uploaded is negative.
